(19) United States
(12) Patent Application Publication
(10) Pub. No.: US 2024/0400896 A1
(43) Pub. Date: Dec. 5, 2024

(54) OXIDE FLUORESCENT MATERIAL AND LIGHT EMITTING DEVICE USING THE SAME

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 18/676,444

(22) Filed: May 28, 2024

(30) Foreign Application Priority Data
May 29, 2023 (JP) 2023-087828

(51) Int. Cl. C09K 11/68; C01B 33/20; C01G 17/00; C01G 37/14; C09K 11/77; H01L 33/50

(52) U.S. Cl. CPC C09K 11/681; C01B 33/20; C01G 17/006; C01G 37/14; C09K 11/685; C09K 11/7708; H01L 33/502; C01P 2002/54; H01L 2933/0041

(57) ABSTRACT

An oxide fluorescent material has a composition represented by the following formula (1).

(Ga₁₋ᵤM¹ᵤ)₂(Ge₁₋ᵥM²ᵥ)_{w}Oₓ:Cr_{y},M³_{z} (1),
wherein M¹ represents at least one element selected from the group consisting of Al, Sc, and In; M² represents at least one element selected from the group consisting of Si, Ti, Zr, Sn, and Hf, M³ represents at least one element selected from the group consisting of Ni, Eu, Fe, Mn, Nd, Tm, Ho, Er, and Yb; and u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

### CROSS-REFERENCE TO RELATED PATENT APPLICATION

This application claims priority to Japanese Patent Application No. 2023-087828, filed on May 29, 2023, the disclosure of which is hereby incorporated by reference in its entirety.

### BACKGROUND

### Technical Field

The present disclosure relates to an oxide fluorescent material and a light emitting device using the same.

### Description of Related Art

Light emitting devices having light emission intensity in a wavelength range from red light to near-infrared light are desired for use in, for example, infrared cameras, infrared communication, light sources for plant growth and cultivation, vein authentication, which is a type of biometric authentication, food composition analyzers for non-destructive measurement of sugar content and other parameters in food or agricultural products such as fruits and vegetables, and analyzers for non-destructive measurement of foreign substances in pharmaceutical products. Light emitting devices that emit light in the wavelength range from red light to near-infrared light as well as in a wavelength range of visible light are also desired.

Examples of such light emitting devices include a light emitting device that combines a light emitting diode (LED) and a fluorescent material.

Examples of the fluorescent material combined in the light emitting device include a fluorescent material having a relatively large light emission intensity of the light emission spectrum in the wavelength range from red light to near-infrared light (hereinafter, also referred to as “near-infrared light emitting fluorescent material”).

As the near-infrared light emitting fluorescent material, Japanese Translation of PCT International Application Publication No. 2020-528486 discloses a fluorescent material having a light emission peak wavelength in a range of 680 nm or more and 760 nm or less and having a composition represented by, for example, CaYAlO₄:Mn⁴⁺. Near-infrared light emitting fluorescent materials with a light emission spectrum in a wavelength range having a wider full width at half maximum and a longer light emission peak wavelength, which are suitable for each application described above, may be needed.

The present disclosure has an object to provide an oxide fluorescent material having a light emission peak wavelength in a wavelength range from red light to near-infrared light and having a wider full width at half maximum of the light emission spectrum, and a light emitting device using the same.

### SUMMARY

A first aspect of the present disclosure relates to an oxide fluorescent material having a composition represented by the following formula (1).

(Ga₁₋ᵤM¹ᵤ)₂(Ge₁₋ᵥM²ᵥ)_{w}Oₓ:Cr_{y},M³_{z} (1),

wherein M¹ represents at least one element selected from the group consisting of Al, Sc, and In; M² represents at least one element selected from the group consisting of Si, Ti, Zr, Sn, and Hf, M³ represents at least one element selected from the group consisting of Ni, Eu, Fe, Mn, Nd, Tm, Ho, Er, and Yb; and u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

A second aspect of the present disclosure relates to a light emitting device including the oxide fluorescent material and a light emitting element emitting light having a light emission peak wavelength in a range of 365 nm or more and 650 nm or less and irradiating the oxide fluorescent material.

The present disclosure can providing an oxide fluorescent material having a light emission peak wavelength in a wavelength range from red light to near-infrared light and having a wider full width at half maximum of the light emission spectrum, and a light emitting device using the same.

### BRIEF DESCRIPTION OF THE DRAWINGS

FIG. 1 is a schematic cross-sectional view showing an exemplary light emitting device according to a first embodiment of the present disclosure.

FIG. 2 is a schematic cross-sectional view showing another exemplary light emitting device according to the first embodiment of the present disclosure.

FIG. 3A is a schematic plan view showing an exemplary light emitting device according to a second embodiment of the present disclosure.

FIG. 3B is a schematic cross-sectional view showing an exemplary light emitting device according to the second embodiment of the present disclosure.

FIG. 4 is a graph showing light emission spectra of the oxide fluorescent materials according to Examples 1 to 5.

FIG. 5 is a graph showing light emission spectra of the oxide fluorescent materials according to Examples 6 to 10.

FIG. 6 is a graph showing light emission spectra of the oxide fluorescent materials according to Examples 11 to 15.

FIG. 7 is a graph showing light emission spectra of the oxide fluorescent materials according to Examples 16 to 18 and Comparative Example 1.

### DETAILED DESCRIPTION

The oxide fluorescent material according to the present disclosure, the light emitting device using the same, and the method for producing an oxide fluorescent material are described below. The embodiments described below are intended to embody the technical idea of the present disclosure, and the present disclosure is not limited to the following oxide fluorescent material and the light emitting device. For visible light, the relationship between color names and chromaticity coordinates, and the relationship between wavelength ranges of light and color names of monochromatic light are in accordance with Japanese Industrial Standard (JIS) Z8110. In this specification, the “fluorescent material” is used in the same meaning as a “fluorescent phosphor”.

Light emitting devices using a fluorescent material are required to emit light in an appropriate wavelength range according to a visual object and conditions of use. For example, in the medical field, there may be a need to easily obtain information inside a living body. The living body includes, for example, water, hemoglobin, and melanin as light absorbers. For example, hemoglobin has a high light absorptance in a visible light wavelength range of less than 650 nm, and with a light emitting device that emits light in the visible light wavelength range, it is difficult for the light in the visible light wavelength range to transmit through the living body, which makes difficult to obtain information inside the living body. If it is possible to irradiate light in a wavelength range where there is little absorption and scattering of light in living tissues, it becomes easier to obtain information deep inside the living body. Therefore, there is a need for a light emitting device capable of emitting light in a wavelength range referred to as a “biological window” where light easily transmits through the living body. The “biological window” may be referred to as a “first biological window” in a wavelength range from around 650 nm to 950 nm, may be referred to as a “second biological window” in a wavelength range from around 1,000 nm to 1,350 nm, and may be referred to as a “third biological window” in a wavelength range from around 1,500 nm to 1,800 nm. If it is possible to irradiate light in a wavelength range where there is little absorption and scattering of light in living tissues, it becomes easier to obtain information deep inside the living body. For example, if the increase or decrease of oxygen concentration in the blood in the living body can be measured by the increase or decrease of light absorption due to hemoglobin that binds to oxygen, the information inside the living body can be easily obtained by irradiating the light emitted from the light emitting device. If the information deep inside the living body can be obtained by irradiating the light emitted from the fluorescent material and the light emitting element, instead of irradiating X-rays or others, it is possible to obtain the information inside the living body more safely. Therefore, the fluorescent material used in the light emitting device may be required to have a light emission peak wavelength in a range of 760 nm or more and 970 nm or less. Recently, there is a need for a light emitting device that emits light in a wavelength range from infrared light to near-infrared light, which is capable of more clearly visualizing deep inside the living body and is highly safe. Light emitting devices including a light emitting element and a fluorescent material are capable of high current flow. The ability to emit light with high output power enables greater detection capability, making it easier to obtain information inside the living body.

In the agricultural and food fields, there is a need for non-destructive sugar content meters for non-destructively measuring the sugar content of agricultural products and fruits and vegetables, and non-destructive taste meters for rice. Near-infrared spectroscopy may be used as a non-destructive method for measuring internal quality such as sugar content, acidity, ripeness, and internal damage of fruits and vegetables, and surface quality such as abnormal drying appearing on the skin surface of fruits and vegetables or in the surface layer near the skin surface. In the near-infrared spectroscopy, fruits and vegetables are irradiated with light in the near-infrared light wavelength range, and the transmitted light that is transmitted through the fruits and vegetables and the reflected light that is reflected by the fruits and vegetables are received to measure the quality of the fruits and vegetables by the decrease in light intensity (light absorption). Light sources such as tungsten or xenon lamps are used in near-infrared spectroscopy analysis devices used in such food fields. In the present specification, the wavelength range of red light is in accordance with JIS Z8110.

In the face of environmental changes such as climate change, it is also desirable to stably supply plants such as vegetables and to increase the production efficiency of plants. Plant factories that can be artificially controlled can stably supply safe vegetables to the market, and are expected to be a next-generation industry. Such plant factories require a light emitting device that emits light capable of promoting the growth of plants. Reaction of plants to light can be grouped into photosynthesis and photomorphogenesis. Photosynthesis is a reaction that uses light energy to decompose water, generate oxygen, and fix carbon dioxide to organic materials, which is a necessary reaction for the growth of plants. Photomorphogenesis is a morphogenetic reaction that uses light as a signal for seed germination, differentiation (germ formation, leaf formation), movement (pore opening and closing, chloroplast movement), and photorefraction. In the photomorphogenesis reaction, it has been found that light in the wavelength range of 690 nm or more and 800 nm or less affects the photoreceptors of plants. Therefore, light emitting devices used in plant factories may be required to be capable of irradiating light in the wavelength range that affects plant photoreceptors (chlorophyll a, chlorophyll b, carotenoids, phytochromes, cryptochromes, and phototropins) and promotes the growth of plants.

As for the above-mentioned near-infrared light emitting fluorescent material, when a light emitting element such as a blue light emitting diode (LED) or laser diode (LD) that emits light from purple to blue is used as an excitation light source in the light emitting device, there is also room for improving the light emission characteristics of the fluorescent material so as to be able to emit light suitable for the intended use.

Light emitting devices that emit light in the red light to near-infrared light wavelength range as well as in the wavelength range of 365 nm or more and less than 700 nm may be required. For example, it may be necessary to emit light in the visible light wavelength range not only to obtain internal information on living bodies or fruits and vegetables, but also to enhance the visibility of objects.

The oxide fluorescent material has a composition represented by the following formula (1).

(Ga₁₋ᵤM¹ᵤ)₂(Ge₁₋ᵥM²ᵥ)_{w}Oₓ:Cr_{y},M³_{z} (1),

wherein M¹ represents at least one element selected from the group consisting of Al, Sc, and In; M² represents at least one element selected from the group consisting of Si, Ti, Zr, Sn, and Hf; M³ represents at least one element selected from the group consisting of Ni, Eu, Fe, Mn, Nd, Tm, Ho, Er, and Yb; and u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

When the parameter y in the formula (1), which represents the molar ratio of the activating element Cr, falls within the range of 0.005 or more and 1.0 or less (0.005≤y≤1.0) in 1 mol of the composition of the oxide fluorescent material, the oxide fluorescent material has a light emission spectrum with a light emission peak wavelength in a desired near-infrared wavelength region depending on the purpose of use, and with a relatively wide full width at half maximum. In the oxide fluorescent material, the parameter y in the formula (1) may be in a range of 0.01 or more and 0.50 or less (0.01≤y≤0.50), may be in a range of 0.01 or more and 0.30 or less (0.01≤y≤0.30), may be in a range of 0.01 or more and 0.20 or less (0.01≤y≤0.20), may be in a range of 0.01 or more and 0.10 or less (0.01≤y≤0.10), may be in a range of 0.01 or more and 0.09 or less (0.01≤y≤0.09), may be in a range of 0.015 or more and 0.08 or less (0.015≤y≤0.08), may be in a range of 0.02 or more and less than 0.08 (0.02≤y<0.08), may be in a range of 0.02 or more and 0.07 or less (0.02≤y≤0.07), or may be in a range of 0.02 or more and 0.06 or less (0.02≤y≤0.06), in 1 mol of the composition of the oxide fluorescent material. In the present specification, in the composition formulae representing the compositions of the fluorescent materials including the oxide fluorescent material, the part before the colon (:) represents elements and the molar ratio constituting a host crystal, and the part after the colon (:) represents an activating element.

In the oxide fluorescent material, the first element M¹ included as necessary may be at least one element selected from the group consisting of Al, Sc, and In, or may be two or more elements selected from the group consisting of Al, Sc, and In in the composition represented by the formula (1). The oxide fluorescent material does not have to contain the first element M¹, but may contain Ga. The oxide fluorescent material may contain Ga partially replaced by the first element M¹, or may contain two or more types of the first element M¹. When the first element M¹ is Al, all of Ga contained in the oxide fluorescent material may be replaced by Al in the composition represented by the formula (1). The oxide fluorescent material does not have to contain Ga; and Ga may be replaced by Al and at least one first element M¹ selected from the group consisting of Sc and In, or may be replaced by two or more types of the first element M¹ in the composition represented by the formula (1).

In the oxide fluorescent material, the molar ratio of the first element M¹ is represented by a product of 2 and the parameter u in the formula (1), wherein the parameter u is in a range of 0 or more and 1.0 or less (0≤u≤1.0) in 1 mol of the composition of the oxide fluorescent material. In the oxide fluorescent material, the parameter u in the formula (1) may be in a range of 0 or more and less than 1.0 (0≤u<1.0), may be in a range of 0.05 or more and 0.95 or less (0.05≤u≤0.95), may be in a range of 0.10 or more and 0.90 or less (0.10≤u≤0.90), may be in a range of 0.15 or more and 0.85 or less (0.15≤u≤0.85), or may be in a range of 0.20 or more and 0.80 or less (0.20≤u≤0.80). The oxide fluorescent material does not have to substantially contain the first element M¹, and the parameter u may be substantially 0 (substantially u=0) in the composition represented by the formula (1). In the present specification, when the numerical value of the parameter representing the molar ratio of the element in the composition is “substantially 0”, it means that the element is not intentionally contained. The numerical value of the parameter representing the molar ratio of the element in the composition being substantially 0 specifically means the case where the content is 1,000 ppm by mass or less, 500 ppm by mass or less, or 1 ppm by mass or more.

In the oxide fluorescent material, the second element M² included as necessary in the composition represented by the formula (1) is at least one element selected from the group consisting of Si, Ti, Zr, Sn, and Hf. In order for the oxide fluorescent material to obtain a light emission spectrum with a light emission peak wavelength in a desired near-infrared wavelength region depending on the purpose of use, and with a wider full width at half maximum, the second element M² included as necessary in the composition represented by the formula (1) may be either Si or Hf, or may be Si.

When the parameter w in the formula (1), which represents the total molar ratio of Ge and the second element M², falls within the range of 1.0 or more and 3.0 or less (1.0≤w≤3.0) in 1 mol of the composition of the oxide fluorescent material, the oxide fluorescent material has a light emission spectrum with a light emission peak wavelength in a desired near-infrared wavelength region depending on the purpose of use, and with a wider full width at half maximum. In the oxide fluorescent material, the parameter w in the formula (1) may be in a range of 1.5 or more and 3.0 or less (1.5≤ w≤3.0). In 1 mol of the composition of the oxide fluorescent material, the total molar ratio of Ga and the first element M¹ and the total molar ratio of Ge and the second element M² may be the same value. The parameter w, which represents the total molar ratio of Ge and the second element M², may be smaller or larger than 2, which represents the total molar ratio of Ga and the first element M¹, when it falls within the range of 1.0 or more and 3.0 or less in 1 mol of the composition of the oxide fluorescent material.

In the oxide fluorescent material, the molar ratio of the second element M² included as necessary is represented by a product of the parameter v and the parameter w in the formula (1), wherein the parameter v is in a range of 0 or more and 0.5 or less (0≤v≤0.5), may be in a range of 0 or more and 0.4 or less (0≤v≤0.4), or may be in a range of 0 or more and 0.3 or less (0≤v≤0.3), in 1 mol of the composition of the oxide fluorescent material. The oxide fluorescent material does not have to substantially contain the second element M², and the parameter v may be substantially 0 (v=0) in the composition represented by the formula (1).

In order for the oxide fluorescent material to obtain a light emission spectrum with a light emission peak wavelength in a desired near-infrared wavelength region depending on the purpose of use, and with a wider full width at half maximum, the parameter x in the formula (1), which represents the molar ratio of oxygen, is in a range of 5 or more and 9 or less (5≤x≤9), may be in a range of 5.5 or more and 8.5 or less (5.5≤x≤8.5), or may be in a range of 6 or more and 8 or less (6≤ x≤8), in 1 mol of the composition of the oxide fluorescent material.

In the oxide fluorescent material, the third element M³ included as necessary in the composition represented by the formula (1) is at least one element selected from the group consisting of Ni, Eu, Fe, Mn, Nd, Tm, Ho, Er, and Yb, or may be at least one element selected from the group consisting of Ni, Eu, Fe, Mn, and Nd.

In the oxide fluorescent material, the parameter z representing the molar ratio of the third element M³, which is also the activating element as Cr and is included as necessary, in the composition represented by the formula (1) is in a range of 0 or more and 0.5 or less (0≤z≤0.5), may be in a range of 0 or more and 0.4 or less (0≤z≤0.4), may be in a range of 0 or more and 0.3 or less (0≤z≤0.3), may be in a range of 0 or more and 0.2 or less (0≤z≤0.2), may be in a range of 0 or more and 0.1 or less (0≤z≤0.1), or may be 0.001 or more (0.001≤z), in 1 mol of the composition of the oxide fluorescent material. The oxide fluorescent material does not have to substantially contain the third element M³, and the parameter z may be substantially 0 (z=0) in the composition represented by the formula (1).

The oxide fluorescent material preferably has a light emission spectrum in which a light emission intensity at 1,000 nm is 25% or more relative to the light emission intensity at the light emission peak wavelength as 100%. When the oxide fluorescent material has a light emission spectrum in which a light emission intensity at 1,000 nm is 25% or more relative to the light emission intensity at the light emission peak wavelength as 100%, the oxide fluorescent material emits light having a light emission intensity required for analysis in a wavelength range of 900 nm or more and 1,100 nm or less, which facilitates obtaining information inside living bodies or information on agricultural products, foods, and pharmaceutical products in a non-destructive manner, and it can be used in light emitting devices for analysis in place of a tungsten or xenon lamp.

The oxide fluorescent material preferably has a full width at half maximum in a range of 150 nm or more and 290 nm or less in a light emission spectrum with a light emission peak wavelength. The oxide fluorescent material preferably converts the wavelength of excitation light emitted from the light emitting element to emit light having a light emission spectrum with a light emission peak wavelength in the desired range, with a wider full width at half maximum, and with a light emission intensity at a desired wavelength required for analysis or other purposes.

When light having a light emission spectrum with a wider full width at half maximum can be irradiated in the wavelength range where information inside living bodies and on agricultural products can be obtained in a non-destructive manner, it is easier to obtain information inside living bodies and on agricultural products. It is also desirable for the color appearance of an object when irradiated with light (hereinafter, also referred to as “color rendering property”) to have a light emission spectrum in a wider wavelength range, and the wider the full width at half maximum, the better the color rendering property of light can be emitted. For example, when emitting light in a wavelength range that affects plant growth in a plant factory, it may be necessary to emit light that does not disturb the spectral balance of the light so that workers can work comfortably. The full width at half maximum in the light emission spectrum with the light emission peak wavelength in the oxide fluorescent material may be 155 nm or more, may be 160 nm or more, may be 165 nm or more, may be 170 nm or more, may be 175 nm or more, or 180 nm or more; may be 285 nm or less, may be 280 nm or less, may be 275 nm or less, may be 270 nm or less, may be 265 nm or less, may be 260 nm or less, may be 250 nm or less, may be 240 nm or less, may be 230 nm or less, or 220 nm or less; or may be in a range of 180 nm or more and 220 nm or less. In the present specification, the full width at half maximum refers to a wavelength width where the light emission intensity is 50% at the light emission peak wavelength indicating the maximum light emission intensity in the light emission spectrum.

The oxide fluorescent material preferably has a light emission spectrum with a light emission peak wavelength in a range of 760 nm or more and 970 nm or less. The oxide fluorescent material preferably has a light emission spectrum in which the oxide fluorescent material converts the wavelength of excitation light emitted from the light emitting element to be an alternative light source to a tungsten or xenon lamp, and in which the light emission intensity required for analysis can be obtained in a wavelength range that facilitates obtaining information inside living bodies and on agricultural products. When the oxide fluorescent material has a light emission spectrum with a light emission peak wavelength in the range of 760 nm or more and 970 nm or less, a light emission spectrum having a light emission intensity required for analysis can be obtained in a wavelength range that facilitates obtaining information inside living bodies or information on agricultural products, foods, and pharmaceutical products in a non-destructive manner. More preferably, the oxide fluorescent material has a light emission spectrum with a light emission peak wavelength in a range of 780 nm or more and 970 nm or less, even more preferably in a range of 790 nm or more and 970 nm or less, still more preferably in a range of 800 nm or more and 970 nm or less, still more preferably in a range of 820 nm or more and 970 nm or less, and particularly preferably in a range of 870 nm or more and 970 nm or less.

The light emitting device includes an oxide fluorescent material having a composition represented by the formula (1) and a light emitting element having a light emission peak wavelength in a range of 365 nm or more and 650 nm or less and irradiating the oxide fluorescent material. The oxide fluorescent material can be used as a member constituting a wavelength conversion member together with a light transmissive material.

A semiconductor element can be used as the light emitting element for irradiating the oxide fluorescent material. For example, a nitride semiconductor can be selected as the material for the light emitting element that emits green or blue light. Materials such as In_{X}Al_{Y}Ga_{1-X-Y}N (0≤X≤1, 0≤Y≤1, X+Y≤1) can be used as the material for the semiconductor structure constituting the light emitting element. For example, a gallium-aluminum-arsenic semiconductor or an aluminum-indium-gallium-phosphorus semiconductor can be selected as the material for the light emitting element that emits red light. For example, an LED chip or an LD chip is preferably used for the light emitting element.

The light emitting element may have a light emission peak wavelength in a range of 365 nm or more and 650 nm or less, may have a light emission peak wavelength in a range of 365 nm or more and 500 nm or less, may have a light emission peak wavelength in a range of 370 nm or more and 490 nm or less, or may have a light emission peak wavelength in a range of 375 nm or more and 480 nm or less. The light emitting element may have a light emission peak wavelength in a range of more than 500 nm and 650 nm or less, may have a light emission peak wavelength in a range of 510 nm or more and 650 nm or less, or may have a light emission peak wavelength in a range of 520 nm or more and 650 nm or less. By using the light emitting element as the excitation light source of the oxide fluorescent material, a light emitting device that emits mixed color light of light emitted from the light emitting element and fluorescence emitted from the fluorescent material containing the oxide fluorescent material in a desired wavelength range can be constituted. The full width at half maximum of the light emission peak in the light emission spectrum of the light emitting element can be, for example, 30 nm or less. For example, a light emitting element using a nitride-based semiconductor is preferably used as the light emitting element. By using a light emitting element using a nitride-based semiconductor as the excitation light source, a stable light emitting device having high efficiency, high input-output linearity, and high resistance to mechanical impacts can be obtained. The light emitting device, which includes a light emitting element that emits red light and an oxide fluorescent material that converts the wavelength of the light emitted from the light emitting element to emit light in the near-infrared wavelength range, can also be used as a heat source, and is useful in cold regions, for example, to prevent snow from accretion on traffic signals and automobile lighting devices.

The light emitting device necessarily includes a first fluorescent material containing the oxide fluorescent material described above, and may further include a fluorescent material having a different composition. The light emitting device preferably includes, in addition to the first fluorescent material, at least one fluorescent material selected from the group consisting of a second fluorescent material having a light emission peak wavelength in a range of 455 nm or more and less than 495 nm, a third fluorescent material having a light emission peak wavelength in a range of 495 nm or more and less than 610 nm, a fourth fluorescent material having a light emission peak wavelength in a range of 610 nm or more and less than 700 nm, and a fifth fluorescent material having a light emission peak wavelength in a range of 700 nm or more and 1,050 nm or less, in the light emission spectrum of each fluorescent material. The light emitting device includes a light emitting element, a first fluorescent material containing the oxide fluorescent material described above, and at least one fluorescent material selected from the group consisting of a second fluorescent material, a third fluorescent material, a fourth fluorescent material, and a fifth fluorescent material, so that the light emitting device can be used as a light source that emits light having a light emission spectrum in a wavelength range from visible light to part of near-infrared light. The light emitting device can be used as a light source that has a light emission spectrum similar to that of conventionally used tungsten and xenon lamps and can be downsized compared to tungsten and xenon lamps. A small light emitting device can be mounted on small mobile devices such as smartphones and smartwatches to obtain information in a living body, which can be used to manage physical conditions.

The light emitting device can be used, for example, in a reflection spectroscopic measuring device, and a lighting device capable of non-destructively measuring a living body, fruits and vegetables, and the like, and requiring light with a good color rendering property.

The second fluorescent material, which has a composition different from that of the first fluorescent material containing the oxide fluorescent material described above, preferably contains at least one fluorescent material selected from the group consisting of a phosphate fluorescent material having a composition represented by the following formula (2a), an aluminate fluorescent material having a composition represented by the following formula (2b), and an aluminate fluorescent material having a composition represented by the following formula (2c); and may contain two or more fluorescent materials of these.

(Ca,Sr,Ba,Mg)₁₀(PO₄)₆(F,Cl,Br,I)₂:Eu (2a)

(Ba,Sr,Ca)MgAl₁₀O₁₇:Eu (2b)

Sr₄Al₁₄O₂₅:Eu (2c)

In the present specification, plural elements sectioned by comma (,) in the composition formulae mean that at least one of these plural elements is contained in the composition.

The third fluorescent material preferably contains at least one fluorescent material selected from the group consisting of a silicate fluorescent material having a composition represented by the following formula (3a), an aluminate fluorescent material or a gallate fluorescent material having a composition represented by the following formula (3b), a β-SiAlON fluorescent material having a composition represented by the following formula (3c), a cesium lead halide fluorescent material having a composition represented by the following formula (3d), and a nitride fluorescent material having a composition represented by the following formula (3e); and may contain two or more fluorescent materials of these. In the case where the third fluorescent material contains two or more fluorescent materials, each of the two or more third fluorescent materials preferably has a light emission peak wavelength in a range different from each other within a range of 495 nm or more and less than 610 nm.

(Ca,Sr,Ba)₈MgSi₄O₁₆(F,Cl,Br)₂:Eu (3a)

(Lu,Y,Gd,Tb)₃(Al,Ga)₅O₁₂:Ce (3b)

Si_{6-z}Al_{z}O_{z}N_{8-z}:Eu (0<z≤4.2) (3c)

CsPb(F,Cl,Br)₃ (3d)

(La,Y,Gd)₃Si₆N₁₁:Ce (3e)

The fourth fluorescent material preferably contains at least one fluorescent material selected from the group consisting of a nitride fluorescent material having a composition represented by the following formula (4a), a fluoro-germanate fluorescent material having a composition represented by the following formula (4b), an oxynitride fluorescent material having a composition represented by the following formula (4c), a fluoride fluorescent material having a composition represented by the following formula (4d), a fluoride fluorescent material having a composition represented by the following formula (4e), a nitride fluorescent material having a composition represented by the following formula (4f), and a nitride fluorescent material having a composition represented by the following formula (4g); and may contain two or more fluorescent materials of these. In the case where the fourth fluorescent material contains two or more fluorescent materials, each of the two or more fluorescent materials preferably has a light emission peak wavelength in a different range within a range of 610 nm or more and less than 700 nm.

(Sr,Ca)AlSiN₃:Eu (4a)

3.5MgO·0.5MgF₂·GeO₂:Mn (4b)

(Ca,Sr,Mg)ₖSi₁₂₋₍ₘ₊ₙ₎Alₘ₊ₙOₙN₁₆₋ₙ:Eu (4c)
wherein k, m, and n satisfy 0<k≤2.0, 2.0≤m≤6.0, and 0≤n≤2.0, respectively,

A¹_{c1}[M⁵_{1-b1}Mn⁴⁺_{b1}F_{d1}] (4d)
wherein A¹ includes at least one selected from the group consisting of K⁺, Li⁺, Na⁺, Rb⁺, Cs⁺, and NH₄⁺, among which K⁺ is preferred; M5 includes at least one element selected from the group consisting of Group 4 elements and Group 14 elements, among which Si and Ge are preferred; b1 satisfies 0<b1<0.2; c1 represents the absolute value of the charge of [M⁵_{1-b1}Mn⁴⁺_{b1}F_{d1}] ions; and d1 satisfies 5<d1<7.

A²_{c2}[M⁶_{1-b2}Mn⁴⁺_{b2}F_{d2}] (4e)

wherein A² includes at least one selected from the group consisting of K⁺, Li⁺, Na⁺, Rb⁺, Cs⁺, and NH₄⁺, among which K⁺ is preferred; M⁶ includes a Group 13 element, and may further include at least one element selected from the group consisting of Group 4 elements and Group 14 elements, among which the Group 13 element is preferably Al, and the 14 element is preferably Si; b2 satisfies 0<b2<0.2; c2 represents the absolute value of the charge of [M⁶_{1-b2}Mn⁴⁺_{b2}F_{d2}] ions; and d2 satisfies 5<d2<7.

(Ba,Sr,Ca)₂Si₅N₈:Eu (4f)

(Sr,Ca)LiAl₃N₄:Eu (4g)

The fifth fluorescent material preferably contains at least one fluorescent material selected from the group consisting of a gallate fluorescent material having a composition represented by the following formula (5a), an aluminate fluorescent material having a composition represented by the following formula (5b), a gallate fluorescent material having a composition represented by the following formula (5c), an aluminate fluorescent material having a composition represented by the following formula (5d), a fluorescent material having a composition represented by the following formula (5e) different from that of the above oxide fluorescent material, a fluorescent material having a composition represented by the following formula (5f) different from that of the above oxide fluorescent material, and a fluorescent material having a composition represented by the following formula (5g) different from that of the above oxide fluorescent material; and may contain two or more fluorescent materials of these.

Ga₂O₃:Cr (5a)

Al₂O₃:Cr (5b)

ZnGa₂O₄:Cr (5c)

(Lu,Y,Gd,Tb)₃(Al,Ga)₅O₁₂:Ce,Cr (5d)

M⁷_{g}M⁸ₕM⁹ᵢM¹⁰₅Oⱼ:Crₑ,M¹¹_{f} (5e)
wherein M⁷ represents at least one element selected from the group consisting of Li, Na, Ka, Rb, and Cs; M⁸ represents at least one element selected from the group consisting of Mg, Ca, Sr, Ba, and Zn; M⁹ represents at least one element selected from the group consisting of Ba, Al, Ga, In, and rare earth elements; M¹⁰ represents at least one element selected from the group consisting of Si, Ti, Ge, Zr, Sn, Hf, and Pb; M¹¹ represents at least one element selected from the group consisting of Eu, Ce, Tb, Pr, Nd, Sm, Yb, Ho, Er, Tm, Ni, and Mn; and e, f, g, h, i, and j satisfy 0<e≤0.2, 0≤f≤0.1, f<e, 0.7≤ g≤1.3, 1.5≤h≤2.5, 0.7≤i≤1.3, and 12.9≤j≤15.1, respectively.

(Mg₁₋ₜ₁M¹²ₜ₁)ᵤ₁(Ga_{1-v1-x1-y1}^{M13}ᵥ₁)₂O_{w1}:Crₓ₁,M¹⁴_{y1} (5f)
wherein M¹² represents at least one element selected from the group consisting of Ca, Sr, Ba, Ni, and Zn; M¹³ represents at least one element selected from the group consisting of B, Al, Sc, and In; M¹⁴ represents at least one element selected from the group consisting of Eu, Ce, Tb, Pr, Nd, Sm, Yb, Ho, Er, Tm, and Mn; and t1, u1, v1, w1, x1, and y1 satisfy 0≤t1≤0.8, 0.7≤u1≤1.3, 0≤v1≤0.8, 3.7≤w1≤4.3, 0.02<x1≤0.3, 0≤y1≤0.2, and y1<x1, respectively.

(Li₁₋ₜ₂M¹⁵ₜ₂)ᵤ₂(Ga₁₋ᵥ₂M¹⁶ᵥ₂)₅O_{w2}:Crₓ₂,Ni_{y2},M¹⁷_{z2} (5g)

wherein M¹⁵ represents at least one element selected from the group consisting of Na, K, Rb, and Cs; M¹⁶ represents at least one element selected from the group consisting of B, Al, Sc, In, and rare earth elements; M¹⁷ represents at least one element selected from the group consisting of Si, Ge, Sn, Ti, Zr, Hf, Bi, V, Nb, and Ta; and t2, u2, v2, w2, x2, y2, and z2 satisfy 0≤ t2≤1.0, 0.7<u2≤1.6, 0≤v2<1.0, 7.85≤ w2≤11.5, 0.05≤x2≤1.2, 0≤y2≤0.5, 0.25<x2+y2≤1.2, y2<x2, and 0≤z2≤0.5, respectively.

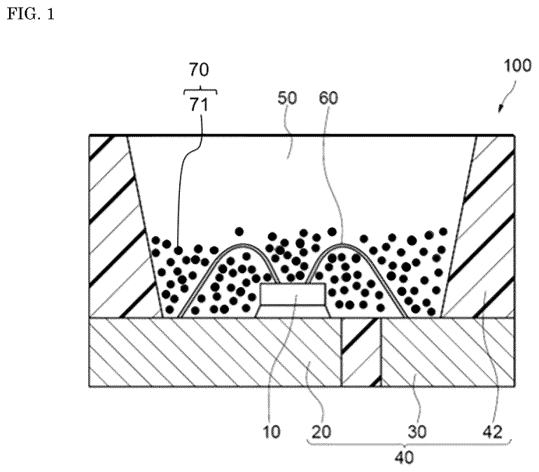

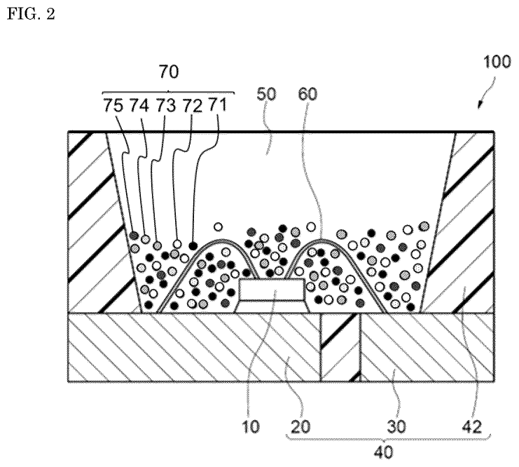

An example of the light emitting device is described with reference to the drawings. FIG. 1 is a schematic cross-sectional view showing an exemplary light emitting device according to a first embodiment of the present disclosure. FIG. 2 is a schematic cross-sectional view showing another exemplary light emitting device according to the first embodiment of the present disclosure.

As shown in FIG. 1, a light emitting device 100 is provided with a formed body 40 having a recessed portion, a light emitting element 10 serving as an excitation light source, and a wavelength conversion member 50 that covers the light emitting element 10. The formed body 40 is formed by monolithically forming a first lead 20, a second lead 30, and a resin portion 42 containing a thermoplastic resin or a thermosetting resin. In the formed body 40, at least the first lead 20 and the second lead 30 constitute the bottom surface of the recessed portion, and at least the resin portion 42 constitutes the lateral surfaces of the recessed portion. The light emitting element 10 is mounted on the bottom surface of the recessed portion of the formed body 40. The light emitting element 10 has a pair of positive and negative electrodes, and the pair of positive and negative electrodes are respectively electrically connected to the first lead 20 and the second lead 30 via a wire 60. The light emitting element 10 is covered by the wavelength conversion member 50. The wavelength conversion member 50 includes a fluorescent material 70 that converts the wavelength of light emitted from the light emitting element 10, and a light transmissive material. The fluorescent material 70 necessarily contains a first fluorescent material 71 containing an oxide fluorescent material. The fluorescent material 70 may contain a fluorescent material having a light emission peak wavelength in a wavelength range different from that of the first fluorescent material 71 and having a composition different from that of the first fluorescent material 71. As shown in FIG. 2, the fluorescent material 70 preferably contains at least one fluorescent material selected from the group consisting of the second fluorescent material 72, the third fluorescent material 73, the fourth fluorescent material 74, and the fifth fluorescent material 75 described above, and may contain two or more types of these. The fluorescent material 70 necessarily contains the first fluorescent material 71, and may contain the second fluorescent material 72, the third fluorescent material 73, the fourth fluorescent material 74, and the fifth fluorescent material 75. The wavelength conversion member 50 also functions as a member for protecting, for example, the light emitting element 10, the wire 60, and the fluorescent material 70 from the external environment. The light emitting device 100 emits light by receiving external electric power through the first lead 20 and the second lead 30.

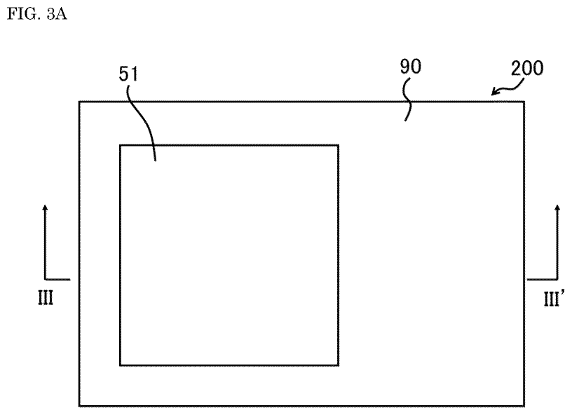

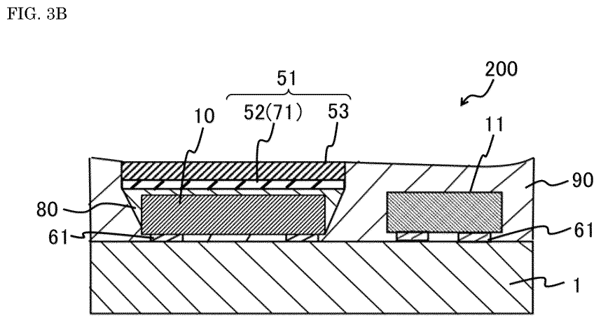

FIGS. 3A and 3B show an exemplary light emitting device according to a second embodiment of the present disclosure. FIG. 3A is a schematic plan view of a light emitting device 200. FIG. 3B is a schematic cross-sectional view of the III-III′ line of the light emitting device 200 shown in FIG. 3A. The light emitting device 200 includes a light emitting element 10 having a light emission peak wavelength in a range of 365 nm or more and 650 nm or less, and a wavelength conversion member 51 including a wavelength conversion body 52 containing a first fluorescent material 71 that is excited by light emitted from the light emitting element 10 and emits light, and a light transmissive body 53 on which the wavelength conversion body 52 is disposed. The light emitting element 10 is flip-chip mounted on a substrate 1 via bumps that are conductive members 61. The wavelength conversion body 52 of the wavelength conversion member 51 is disposed on the light emitting surface of the light emitting element 10 via an adhesive layer 80. The lateral surface(s) of the light emitting element 10 and the lateral surface(s) of the wavelength conversion member 51 are covered with a covering member 90 that reflects light. The wavelength conversion body 52 is excited by light emitted from the light emitting element 10 and necessarily contains the first fluorescent material 71 containing an oxide fluorescent material. The wavelength conversion body 52 may contain at least one selected from the group consisting of the second fluorescent material, the third fluorescent material, the fourth fluorescent material, and the fifth fluorescent material. The light emitting element 10 is capable of receiving electric power from the outside of the light emitting device 200 via the wiring and the conductive members 61 formed on the substrate 1, thereby enabling the light emitting device 200 to emit light. The light emitting device 200 may include a semiconductor element 11 such as a protective element for preventing the light emitting element 10 from being broken due to excessive voltage application. The covering member 90 is disposed so as to cover, for example, the semiconductor element 11. Each member used in the light emitting device is described below. For the details, for example, the disclosure of Japanese Unexamined Patent Publication No. 2014-112635 may be referred to.

Examples of the light transmissive material constituting the wavelength conversion body together with the fluorescent material include at least one selected from the group consisting of resin, glass, and inorganic substances. The resin can use at least one resin selected from the group consisting of a silicone resin, an epoxy resin, a phenol resin, a polycarbonate resin, an acrylic resin, and modified resins thereof. Among them, a silicone resin and a modified silicone resin are preferred because of their good heat and light resistance. The wavelength conversion member may optionally include a filler, a colorant, and a light diffusing material in addition to the fluorescent material and the light transmissive material. Examples of the filler include silicon oxide, barium titanate, titanium oxide, and aluminum oxide.

The light transmissive body can use a plate-shaped body formed of a light transmissive material such as glass or resin. Examples of the glass include borosilicate glass and quartz glass. Examples of the resin include a silicone resin and an epoxy resin. When the wavelength conversion member includes a substrate, the substrate is preferably formed of an insulating material that is difficult to transmit light from the light emitting element and external light. Examples of the material of the substrate include ceramics such as aluminum oxide and aluminum nitride, and resins such as a phenol resin, an epoxy resin, a polyimide resin, a bismaleimide triazine resin (BT resin), and a polyphthalamide (PPA) resin. When an adhesive layer is interposed between the light emitting element and the wavelength conversion member, the adhesive constituting the adhesive layer is preferably formed of a material capable of optically connecting the light emitting element and the wavelength conversion member. The material constituting the adhesive layer is preferably at least one resin selected from the group consisting of an epoxy resin, a silicone resin, a phenol resin, and a polyimide resin. The light transmissive body does not have to be disposed on the wavelength conversion member.

Examples of the semiconductor element optionally disposed in the light emitting device include a transistor for controlling the light emitting element and a protective element for suppressing the destruction and the performance deterioration of the light emitting element due to excessive voltage application. Examples of the protective element include a Zener diode. When the light emitting device includes a covering member, it is preferable to use an insulating material as the material of the covering member. More specific examples thereof include a phenol resin, an epoxy resin, a bismaleimide triazine resin (BT resin), a polyphthalamide (PPA) resin, and a silicone resin. A colorant, a fluorescent material, and a filler may be optionally added to the covering member. The light emitting device may use bumps as conductive members. Examples of the material of the bumps include Au and an alloy thereof, and examples of the other conductive member include eutectic solder (Au—Sn), Pb—Sn, and lead-free solder.

An example of the method for producing an exemplary light emitting device according to the first embodiment is described below. For the details, for example, the disclosure of Japanese Unexamined Patent Publication No. 2010-062272 may be referred to. The method for producing a light emitting device preferably includes a step of providing a formed body, a step of disposing a light emitting element, a step of disposing a wavelength conversion member-forming composition, and a step of forming a resin package. When using a block of a plurality of formed bodies each having a recessed portion, the production method may include an individualizing step of separating each resin package in each unit region after the step of forming a resin package.

In the step of providing a formed body, a plurality of leads are monolithically formed using a thermosetting resin or a thermoplastic resin to provide a formed body having a recessed portion with lateral surface(s) and a bottom surface. The formed body may be formed from a block substrate including a plurality of recessed portions.

In the step of disposing a light emitting element, the light emitting element is disposed on the bottom surface of the recessed portion of the formed body, and the positive and negative electrodes of the light emitting element are connected to the first lead and the second lead, respectively, by a wire.

In the step of disposing a wavelength conversion member-forming composition, the wavelength conversion member-forming composition is disposed in the recessed portion of the formed body.

In the step of forming a resin package, the wavelength conversion member-forming composition disposed in the recessed portion of the formed body is cured to form a resin package, thereby producing a light emitting device. When using a plurality of formed bodies formed from a block substrate having a plurality of recessed portions, in the individualizing step after the step of forming a resin package, the resin package is separated for each resin package in each unit region from the block substrate having a plurality of recessed portions, thereby producing individual light emitting devices. As described above, the light emitting devices shown in FIGS. 1 and 2 can be produced.

An example of the method for producing an exemplary light emitting device according to the second embodiment is described below. For the details, for example, the disclosure of Japanese Unexamined Patent Publication No. 2014-112635 or Japanese Unexamined Patent Publication No. 2017-117912 may be referred to. The method for producing a light emitting device preferably includes a step of disposing a light emitting element, a discretionary step of disposing a semiconductor element, a step of forming a wavelength conversion member including a wavelength conversion body, a step of adhering a light emitting element and a wavelength conversion member, and a step of forming a covering member.

For example, in the step of disposing a light emitting element, the light emitting element is disposed on the substrate. The light emitting element and the semiconductor element are flip-chip mounted, for example, on the substrate. Subsequently, in the step of forming a wavelength conversion member including a wavelength conversion body, the wavelength conversion body may be obtained by forming a plate-shaped, sheet-shaped, or layered wavelength conversion body on one surface of the light transmissive body by a printing method, an adhesive method, a compression molding method, or an electrodeposition method. For example, in the printing method, a wavelength conversion body composition containing a fluorescent material and a resin serving as a binder or a solvent can be printed on one surface of the light transmissive body to form a wavelength converter member including a wavelength conversion body. Subsequently, in the step of adhering a light emitting element and a wavelength conversion member, the wavelength conversion member is allowed to face the light emitting surface of the light emitting element, and the wavelength conversion member is adhered onto the light emitting element by the adhesive layer. Subsequently, in the step of forming a covering member, the lateral surfaces of the light emitting element and the wavelength conversion member are covered with the composition for a covering member. The covering member is intended to reflect light emitted from the light emitting element, and when the light emitting device includes a semiconductor element, it is preferable to form the covering member such that the semiconductor element is embedded by the covering member. As described above, the light emitting device shown in FIGS. 3A and 3B can be produced.

The method for producing an oxide fluorescent material includes: providing a first compound containing Ga and/or a second compound containing at least one first element M¹ selected from the group consisting of Al, Sc, and In, a third compound containing Ge, a fourth compound containing Cr, optionally a fifth compound containing at least one second element M² selected from the group consisting of Si, Ti, Zr, Sn, and Hf, and optionally a sixth compound containing at least one third element M³ selected from the group consisting of Ni, Eu, Fe, Mn, Nd, Tm, Ho, Er, and Yb; adjusting and mixing the first compound and/or the second compound, the third compound, the fourth compound, optionally the fifth compound, and optionally the sixth compound to provide a raw material mixture such that, when the total molar ratio of Ga and/or the at least one first element M¹ in 1 mol of the composition of the oxide fluorescent material is 2, the molar ratio of the at least one first element M¹ is a product of the parameter u and 2, the parameter u is a numerical value of 0 or more and 1.0 or less, the molar ratio of Ga is a product of 1 minus the parameter u and 2, the molar ratio of the at least one second element M² is a product of the parameter v and the parameter w, the parameter v is a numerical value of 0 or more and 0.5 or less, the parameter w is a numerical value of 1.0 or more and 3.0 or less, the molar ratio of Ge is a product of 1 minus the parameter v and the parameter w, the molar ratio of Cr is the parameter y, the parameter y is a numerical value of 0.005 or more and 1.0 or less, the molar ratio of the at least one third element M³ is the parameter z, and the parameter z is a numerical value of 0 or more and 0.5 or less; and heat-treating the raw material mixture at a temperature in a range of 800° C. or higher and 1,400° C. or lower in an atmosphere containing oxygen to obtain an oxide fluorescent material, wherein at least one selected from the group consisting of the first compound, the second compound, the third compound, and the fourth compound preferably uses an oxide. The oxide fluorescent material to be obtained preferably has a molar ratio of each element of the oxide fluorescent material in the same or similar range as the supplied composition for obtaining the raw material mixture in 1 mol of the composition of the oxide fluorescent material.

The raw materials for producing an oxide fluorescent material include a first compound containing Ga, a third compound containing Ge, and a fourth compound containing Cr, and may include a second compound containing the first element M¹ included as necessary, a fifth compound containing the second element M² included as necessary, and a sixth compound containing the third element M³ included as necessary. The raw materials for producing an oxide fluorescent material include a second compound containing the first element M¹, a third compound containing Ge, and a fourth compound containing Cr; and may include a fifth compound containing the second element M² included as necessary, and a sixth compound containing the third element M³ included as necessary. Examples of the first compound, the second compound, the third compound, the fourth compound, the fifth compound, and the sixth compound include oxides, carbonates, and chlorides, and hydrates of these, respectively. At least one compound selected from the group consisting of the first compound, the second compound, the third compound, and the fourth compound is an oxide, and two or more compounds may be oxides. The fifth compound containing the second element M² included as necessary or the sixth compound containing the third element M³ included as necessary may be an oxide. The first compound, the second compound, the third compound, the fourth compound, the fifth compound, and the sixth compound are preferably in the form of powder.

Examples of the first compound include Ga₂O₃ and GaCl₃. Examples of the second compound include Al₂O₃, AlCl₃, Sc₂O₃, ScCl₃, In₂O₃, and InCl₃. Examples of the third compound include GeO₂ and GeCl₄. Examples of the fourth compound include Cr₂O₃, Cr₂(CO₃)₃, and CrCl. The first compound, the second compound, the third compound, and the fourth compound may be hydrates.

Specific examples of the fifth compound include SiO₂, TiO₂, TiCl₄, ZrO₂, ZrCl₄, SnO₂, SnCl₂, HfO₂, and HfCl₄. The fifth compound may be a hydrate.

Specific examples of the sixth compound include NiO, NiCl₂, Eu₂O₃, EuCl₃, Fe₂O₃, Fe₃O₄, FeCl₂, FeCl₃, FeCO₃, Fe₂(CO₃)₃, MnO, MnO₂, Mn₂O₃, Mn₃O₄, Nd₂(CO₃)₃, Nd₂O₃, NdCl₃, Tm₂O₃, TmCl₃, Ho₂O₃, HoCl₃, Er₂O₃, ErCl, Yb₂O₃, and YbCl₃. The sixth compound may be a hydrate.

The raw material mixture is preferably provided by adjusting and mixing raw materials so as to have a composition represented by the following formula (1). The oxide fluorescent material to be obtained preferably has a composition in which each element of the oxide fluorescent material is the same as or similar to the composition represented by the following formula (1) for obtaining the raw material mixture in 1 mol of the composition of the oxide fluorescent material.

(Ga₁₋ᵤM¹ᵤ)₂(Ge₁₋ᵥM²ᵥ)_{w}Oₓ:Cr_{y},M³_{z} (1),
wherein M¹ represents at least one element selected from the group consisting of Al, Sc, and In; M² represents at least one element selected from the group consisting of Si, Ti, Zr, Sn, and Hf, M³ represents at least one element selected from the group consisting of Ni, Eu, Fe, Mn, Nd, Tm, Ho, Er, and Yb; and u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

In the composition represented by the formula (1) for the raw material mixture, Ga may be replaced by Al in the first element M¹, and may be replaced by two or more first elements M¹ of Al and at least one selected from the group consisting of Sc and In. In the composition represented by the formula (1) for the raw material mixture, the second element M² may be either Si or Hf, and the third element M³ may be at least one element selected from the group consisting of Ni, Eu, Fe, Mn, and Nd.

In the composition represented by the formula (1) for the raw material mixture, u, w, and y preferably satisfy 0≤u<1.0, 1.5≤w≤3.0, and 0.02≤y<0.08, respectively.

The first compound and/or the second compound, the third compound, the fourth compound, the fifth compound included as necessary, and the sixth compound included as necessary, which are weighed such that the elements contained in each compound of the raw material satisfy the aforementioned composition, can be mixed in wet or in dry to obtain a raw material mixture. The weighed compounds may be mixed using a mixing machine. As the mixing machine, for example, a ball mill, a vibration mill, a roll mill, and a jet mill, which are industrially commonly used, can be used.

The raw material mixture may contain a flux. When the raw material mixture contains a flux, the reaction between the raw materials is promoted more and the solid-phase reaction proceeds more uniformly, so that a fluorescent material having a large particle diameter and good light emission characteristics can be obtained. When the temperature of the heat treatment for obtaining a fluorescent material is similar to the temperature at which the liquid phase of the compound used as the flux is formed, the flux promotes the reaction between the raw materials. As a flux, boric acid, a borate containing at least one element selected from the group consisting of alkaline earth metal elements and alkali metal elements, or a halide containing at least one element selected from the group consisting of alkaline earth metal elements and alkali metal elements can be used. Among the halides, fluoride can be used as a flux. For example, boric acid (H₃BO₃) and lithium fluoride (LiF) can be used as fluxes.

The raw material mixture can be placed in a crucible or a boat formed of a material such as graphite or other carbon, boron nitride (BN), alumina (Al₂O₃), tungsten (W), or molybdenum (Mo), and heat-treated in a furnace.

The raw material mixture is heat-treated in an atmosphere containing oxygen. The content of oxygen in the atmosphere is not particularly limited. The content of oxygen in the atmosphere containing oxygen is preferably 5% by volume or more, more preferably 10% by volume or more, and even more preferably 15% by volume or more. The heat treatment is preferably performed in an air atmosphere (oxygen content of 20% by volume or more). When the atmosphere does not contain oxygen, such as an oxygen content of less than 1% by volume, an oxide fluorescent material having a desired composition may not be obtained.

The temperature at which the raw material mixture is heat-treated is in a range of 800° C. or higher and 1,400° C. or lower, preferably in a range of 850° C. or higher and 1,300° C. or lower, more preferably in a range of 870° C. or higher and 1,290° C. or lower, and even more preferably in a range of 900° C. or higher and 1,280° C. or lower. When the heat treatment temperature falls within the range of 800° C. or higher and 1,400° C. or lower, decomposition by heat is suppressed, and a fluorescent material having a desired composition and a stable crystal structure can be obtained.

In the heat treatment, a maintaining time at a predetermined temperature may be set up. The maintaining time may be, for example, in a range of 0.5 hour or more and 48 hours or less, may be in a range of 1 hour or more and 40 hours or less, and may be in a range of 2 hours or more and 30 hours or less. By setting the maintaining time in the range of 0.5 hour or more and 48 hours or less, the crystal growth can be promoted.

The pressure in the heat treatment atmosphere may be standard atmospheric pressure (0.101 MPa), and may be 0.101 MPa or more; and the heat treatment may be performed in a pressurized atmosphere range of 0.11 MPa or more and 200 MPa or less. In the heat-treated product obtained by the heat treatment, the crystal structure is more easily decomposed at a higher heat treatment temperature, but in a pressurized atmosphere, the decomposition of the crystal structure can be suppressed.

The heat treatment time can be appropriately selected depending on the heat treatment temperature and the pressure of the atmosphere during the heat treatment, and is preferably in a range of 0.5 hour or more and 20 hours or less. Even in the case of performing two or more stages of heat treatment, the time for one heat treatment is preferably in a range of 0.5 hour or more and 20 hours or less. When the heat treatment time falls within the range of 0.5 hour or more and 20 hours or less, the decomposition of the heat-treated product obtained is suppressed, and a fluorescent material having a stable crystal structure and a desired light emission intensity can be obtained. In addition, the production cost can be reduced and the production time can be relatively shortened. The heat treatment time is more preferably in a range of 1 hour or more and 10 hours or less, and even more preferably in a range of 1.5 hours or more and 9 hours or less.

The heat-treated product obtained by the heat treatment may be subjected to post-treatments such as pulverization, dispersion, solid-liquid separation, and drying. The solid-liquid separation can be performed according to an industrially commonly used method such as filtration, suction filtration, pressure filtration, centrifugation, or decantation. The drying can be performed using an industrially commonly used apparatus such as a vacuum dryer, a hot air heating dryer, a conical dryer, or a rotary evaporator.

Embodiments according to the present disclosure include the following oxide fluorescent material and the light emitting device using the same. Embodiments according to the present disclosure preferably include the following method for producing an oxide fluorescent material.

[Aspect 1] An oxide fluorescent material, having a composition represented by the following formula (1):

(Ga₁₋ᵤM¹ᵤ)₂(Ge₁₋ᵥM²ᵥ)_{w}Oₓ:Cr_{y},M³_{z} (1),
wherein M¹ represents at least one element selected from the group consisting of Al, Sc, and In; M² represents at least one element selected from the group consisting of Si, Ti, Zr, Sn, and Hf, M³ represents at least one element selected from the group consisting of Ni, Eu, Fe, Mn, Nd, Tm, Ho, Er, and Yb; and u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

[Aspect 2] The oxide fluorescent material according to Aspect 1, wherein y satisfies 0.02≤y<0.08 in the formula (1).

[Aspect 3] The oxide fluorescent material according to Aspect 1 or 2, wherein u satisfies 0≤u<1.0 in the formula (1).

[Aspect 4] The oxide fluorescent material according to any one of Aspects 1 to 3, wherein w satisfies 1.5≤ w≤3.0 in the formula (1).

[Aspect 5] The oxide fluorescent material according to Aspect 3, wherein in a light emission spectrum of the oxide fluorescent material, a light emission intensity at 1,000 nm is 25% or more relative to a light emission intensity at the light emission peak wavelength as 100%.

[Aspect 6] The oxide fluorescent material according to any one of Aspects 1 to 5, wherein the oxide fluorescent material has a full width at half maximum in a light emission spectrum with a light emission peak wavelength in a range of 150 nm or more and 290 nm or less.

[Aspect 7] The oxide fluorescent material according to Aspect 3 or 5, wherein the oxide fluorescent material has a full width at half maximum in a range of 180 nm or more and 220 nm or less in a light emission spectrum with a light emission peak wavelength.

[Aspect 8] The oxide fluorescent material according to any one of Aspects 1 to 7, wherein the oxide fluorescent material has a light emission spectrum with a light emission peak wavelength in a range of 760 nm or more and 970 nm or less. [Aspect 9] The oxide fluorescent material according to Aspect 3, 5, or 7, wherein the oxide fluorescent material has a light emission spectrum with a light emission peak wavelength in a range of 870 nm or more and 970 nm or less.

[Aspect 10] A light emitting device, comprising the oxide fluorescent material according to any one of Aspects 1 to 9 and a light emitting element having a light emission peak wavelength in a range of 365 nm or more and 650 nm or less.

[Aspect 11] A method for producing an oxide fluorescent material, comprising: adjusting and mixing a first compound containing Ga and/or a second compound containing at least one first element M1 selected from the group consisting of Al, Sc, and In, a third compound containing Ge, a fourth compound containing Cr, optionally a fifth compound containing at least one second element M2 selected from the group consisting of Si, Ti, Zr, Sn, and Hf, and optionally a sixth compound containing at least one third element M3 selected from the group consisting of Ni, Eu, Fe, Mn, Nd, Tm, Ho, Er, and Yb to provide a raw material mixture such that: when a total molar ratio of Ga and/or the at least one first element M1 in the composition of the oxide fluorescent material is 2, a molar ratio of the at least one first element M1 is a product of a parameter u and 2, wherein the parameter u is a numerical value of 0 or more and 1.0 or less, a molar ratio of Ga is a product of 2 and a value of 1 minus the parameter u, a molar ratio of the at least one second element M2 is a product of a parameter v and a parameter w, wherein the parameter v is a numerical value of 0 or more and 0.5 or less, wherein the parameter w is a numerical value of 1.0 or more and 3.0 or less, a molar ratio of Ge is a product of the parameter w and a value of 1 minus the parameter v, a molar ratio of Cr is the parameter y, wherein the parameter y is a numerical value of 0.005 or more and 1.0 or less, a molar ratio of the at least one third element M3 is a parameter z, wherein the parameter z is a numerical value of 0 or more and 0.5 or less; and
heat-treating the raw material mixture at a temperature in a range of 800° C. or higher and 1,400° C. or lower in an atmosphere containing oxygen to obtain an oxide fluorescent material,
wherein at least one selected from the group consisting of the first compound, the second compound, the third compound, and the fourth compound comprises an oxide.

[Aspect 12] The method for producing an oxide fluorescent material according to Aspect 11, wherein the raw material mixture has a composition represented by the following formula (1):

(Ga₁₋ᵤM¹ᵤ)₂(Ge₁₋ᵥM²ᵥ)_{w}Oₓ:Cr_{y},M³_{z} (1),
wherein u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

### EXAMPLES

The present disclosure is hereunder specifically described by reference to the following Examples. The present disclosure is not limited to the following Examples.

### Oxide Fluorescent Material

### Example 1

For raw materials, 9.0 g of a first compound Ga₂O₃, 10.0 g of a third compound GeO₂, and 0.07 g of a fourth compound Cr₂O₃ were weighed and used. The raw materials were weighed such that the molar ratio of each element in 1 mol of the composition of the oxide fluorescent material to be obtained was Ga₂Ge₂O₇:Cr_{0.02} in the supplied composition. Using an agate mortar and an agate pestle, the raw materials were mixed for 10 minutes to obtain a raw material mixture. The resulting raw material mixture was placed in an alumina crucible and heat-treated at 1,250° C. for 8 hours in an air atmosphere (20% by volume of oxygen) with standard air pressure (0.101 MPa). After the heat treatment, the resulting heat-treated product was pulverized to obtain an oxide fluorescent material of Example 1 having the composition shown in Table 1, which are the molar ratios in the supplied composition.

### Example 2

For raw materials, 9.0 g of a first compound Ga₂O₃, 10.0 g of a third compound GeO₂, and 0.15 g of a fourth compound Cr₂O₃ were weighed and used. The raw materials were weighed such that the molar ratio of each element in 1 mol of the composition of the oxide fluorescent material to be obtained was Ga₂Ge₂O₇:Cr_{0.04} in the supplied composition. The other procedures were the same as in Example 1 to obtain an oxide fluorescent material of Example 2 having the composition shown in Table 1, which are the molar ratios in the supplied composition.

### Example 3

For raw materials, 9.0 g of a first compound Ga₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Ga₂Ge₂O₇:Cr_{0.06} in the supplied composition. The other procedures were the same as in Example 1 to obtain an oxide fluorescent material of Example 3 having the composition shown in Table 1, which are the molar ratios in the supplied composition.

### Example 4

For raw materials, 9.0 g of a first compound Ga₂O₃, 10.0 g of a third compound GeO₂, and 0.29 g of a fourth compound Cr₂O₃ were weighed and used. The raw materials were weighed such that the molar ratio of each element in 1 mol of the composition of the oxide fluorescent material to be obtained was Ga₂Ge₂O₇:Cr_{0.08} in the supplied composition. The other procedures were the same as in Example 1 to obtain an oxide fluorescent material of Example 4 having the composition shown in Table 1, which are the molar ratios in the supplied composition.

### Example 5

For raw materials, 9.0 g of a first compound Ga₂O₃, 12.5 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Ga₂Ge_{2.5}O₈:Cr_{0.06} in the supplied composition. The other procedures were the same as in Example 1 to obtain an oxide fluorescent material of Example 5 having the composition shown in Table 1, which are the molar ratios in the supplied composition.

### Example 6

For raw materials, 4.5 g of a first compound Ga₂O₃, 2.5 g of a second compound Al₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Ga₁Al₁Ge₂O₇:Cr_{0.06} in the supplied composition. An oxide fluorescent material of Example 6 having the composition shown in Table 1, which are the molar ratios in the supplied composition, was obtained in the same manner as in Example 1 except that the heat treatment temperature was 1,275° C.

### Example 7

For raw materials, 6.8 g of a first compound Ga₂O₃, 1.3 g of a second compound Al₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Ga_{1.5}Al_{0.5}Ge₂O₇:Cr_{0.06} in the supplied composition. In the compositional formula, the molar ratio of elements without numerical values is 1. An oxide fluorescent material of Example 7 having the composition shown in Table 1, which are the molar ratios in the supplied composition, was obtained in the same manner as in Example 1 except that the heat treatment temperature was 1,275° C.

### Example 8

For raw materials, 6.8 g of a first compound Ga₂O₃, 3.3 g of a second compound In₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Ga_{1.5}In_{0.5}Ge₂O₇:Cr_{0.06} in the supplied composition. In the compositional formula, the molar ratio of elements without numerical values is 1. The other procedures were the same as in Example 1 to obtain an oxide fluorescent material of Example 8 having the composition shown in Table 1, which are the molar ratios in the supplied composition.

### Example 9

For raw materials, 6.8 g of a first compound Ga₂O₃, 1.7 g of a second compound Sc₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Ga_{1.5}Sc_{0.5}Ge₂O₇:Cr_{0.06} in the supplied composition. In the compositional formula, the molar ratio of elements without numerical values is 1. The other procedures were the same as in Example 1 to obtain an oxide fluorescent material of Example 9 having the composition shown in Table 1, which are the molar ratios in the supplied composition.

### Example 10

For raw materials, 9.0 g of a first compound Ga₂O₃, 7.5 g of a third compound GeO₂, 1.4 g of a fifth compound SiO₂, and 0.22 g of a fourth compound Cr₂O₃ were weighed and used. The raw materials were weighed such that the molar ratio of each element in 1 mol of the composition of the oxide fluorescent material to be obtained was Ga₂Ge_{1.5}Si_{0.5}O₇:Cr_{0.06} in the supplied composition. An oxide fluorescent material of Example 10 having the composition shown in Table 1, which are the molar ratios in the supplied composition, was obtained in the same manner as in Example 1 except that the heat treatment temperature was 1,300° C.

### Example 11

For raw materials, 4.9 g of a second compound Al₂O₃, 10.0 g of a third compound GeO₂, and 0.07 g of a fourth compound Cr₂O₃ were weighed and used. The raw materials were weighed such that the molar ratio of each element in 1 mol of the composition of the oxide fluorescent material to be obtained was Al₂Ge₂O₇:Cr_{0.02} in the supplied composition. An oxide fluorescent material of Example 11 having the composition shown in Table 1, which are the molar ratios in the supplied composition, was obtained in the same manner as in Example 1 except that the heat treatment temperature was 1,275° C.

### Example 12

For raw materials, 4.9 g of a second compound Al₂O₃, 10.0 g of a third compound GeO₂, and 0.15 g of a fourth compound Cr₂O₃ were weighed and used. The raw materials were weighed such that the molar ratio of each element in 1 mol of the composition of the oxide fluorescent material to be obtained was Al₂Ge₂O₇:Cr_{0.04} in the supplied composition. An oxide fluorescent material of Example 12 having the composition shown in Table 1, which are the molar ratios in the supplied composition, was obtained in the same manner as in Example 1 except that the heat treatment temperature was 1,275° C.

### Example 13

For raw materials, 4.9 g of a second compound Al₂O₃, 10.0 g of a third compound GeO₂, and 0.26 g of a fourth compound Cr₂O₃ were weighed and used. The raw materials were weighed such that the molar ratio of each element in 1 mol of the composition of the oxide fluorescent material to be obtained was Al₂Ge₂O₇:Cr_{0.07} in the supplied composition. An oxide fluorescent material of Example 13 having the composition shown in Table 1, which are the molar ratios in the supplied composition, was obtained in the same manner as in Example 1 except that the heat treatment temperature was 1,275° C.

### Example 14

For raw materials, 4.9 g of a second compound Al₂O₃, 10.0 g of a third compound GeO₂, and 0.37 g of a fourth compound Cr₂O₃ were weighed and used. The raw materials were weighed such that the molar ratio of each element in 1 mol of the composition of the oxide fluorescent material to be obtained was Al₂Ge₂O₇:Cr_{0.10} in the supplied composition. An oxide fluorescent material of Example 14 having the composition shown in Table 1, which are the molar ratios in the supplied composition, was obtained in the same manner as in Example 1 except that the heat treatment temperature was 1,275° C.

### Example 15

For raw materials, 4.9 g of a second compound Al₂O₃, 12.5 g of a third compound GeO₂, and 0.15 g of a fourth compound Cr₂O₃ were weighed and used. The raw materials were weighed such that the molar ratio of each element in 1 mol of the composition of the oxide fluorescent material to be obtained was Al₂Ge_{2.5}O₈:Cr_{0.04} in the supplied composition. An oxide fluorescent material of Example 15 having the composition shown in Table 1, which are the molar ratios in the supplied composition, was obtained in the same manner as in Example 1 except that the heat treatment temperature was 1,275° C.

### Example 16

For raw materials, 4.9 g of a second compound Al₂O₃, 15.0 g of a third compound GeO₂, and 0.15 g of a fourth compound Cr₂O₃ were weighed and used. The raw materials were weighed such that the molar ratio of each element in 1 mol of the composition of the oxide fluorescent material to be obtained was Al₂Ge₃O₉:Cr_{0.04} in the supplied composition. An oxide fluorescent material of Example 16 having the composition shown in Table 1, which are the molar ratios in the supplied composition, was obtained in the same manner as in Example 1 except that the heat treatment temperature was 1,275° C.

### Example 17

For raw materials, 3.7 g of a second compound Al₂O₃, 3.3 g of a second compound In₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Al_{1.5}In_{0.5}Ge₂O₇:Cr_{0.06} in the supplied composition. The other procedures were the same as in Example 1 to obtain an oxide fluorescent material of Example 17 having the composition shown in Table 1, which are the molar ratios in the supplied composition.

### Example 18

For raw materials, 3.7 g of a second compound Al₂O₃, 1.7 g of a second compound Sc₂O₃, 10.0 g of a third compound GeO₂, and 0.22 g of a fourth compound Cr₂O₃ were weighed and used. The raw materials were weighed such that the molar ratio of each element in 1 mol of the composition of the oxide fluorescent material to be obtained was Al_{1.5}Sc_{0.5}Ge₂O₇:Cr_{0.06} in the supplied composition. The other procedures were the same as in Example 1 to obtain an oxide fluorescent material of Example 18 having the composition shown in Table 1, which are the molar ratios in the supplied composition.

### Comparative Example 1

For raw materials, 18.0 g of a first compound Ga₂O₃, 5.5 g of a third compound GeO₂, and 0.15 g of a fourth compound Cr₂O₃ were weighed and used. The raw materials were weighed such that the molar ratio of each element in 1 mol of the composition of the oxide fluorescent material to be obtained was Ga₄Ge₁O₈:Cr_{0.04} in the supplied composition. The other procedures were the same as in Example 1 to obtain an oxide fluorescent material of Comparative Example 1 having the composition shown in Table 1, which are the molar ratios in the supplied composition.

### Measurement of Light Emission Spectrum and Light Emission Characteristics

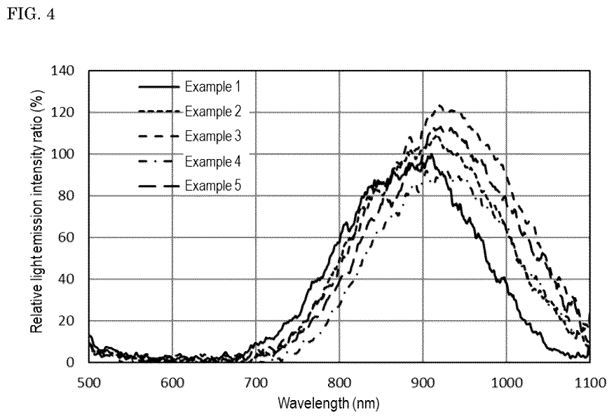

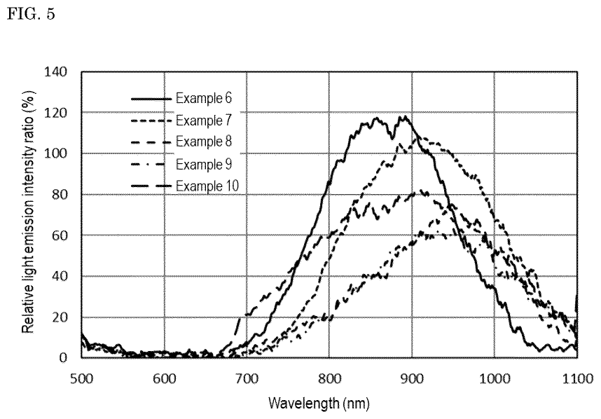

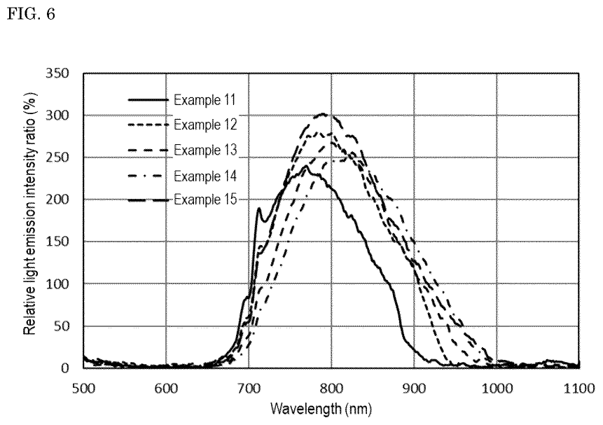

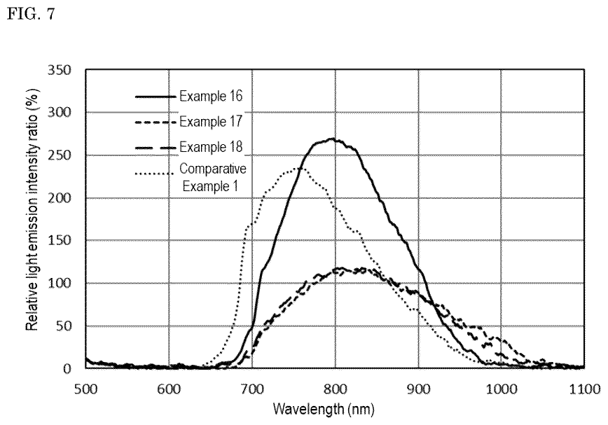

For the oxide fluorescent material in each of Examples and Comparative Example, the light emission spectrum was measured using a quantum efficiency measurement system (QE-2000, manufactured by Otsuka Electronics Co., Ltd.). The light emission peak wavelength of the excitation light used in the quantum efficiency measurement system was 450 nm. From the obtained light emission spectrum of each fluorescent material, the relative light emission intensity, light emission peak wavelength, and full width at half maximum were determined as light emission characteristics. That is, the light emission peak wavelength (λp) (nm) in the light emission spectrum of each fluorescent material and the full width at half maximum (FWHM) (nm) of the light emission spectrum of the light emission peak wavelength were determined. Furthermore, in the light emission spectrum of each oxide fluorescent material, the light emission intensity (%) at 1,000 nm was determined relative to 100% of the light emission intensity of the light emission peak wavelength. The light emission intensity of the oxide fluorescent material according to Example 1 was defined as 100%, and the light emission intensity of the oxide fluorescent material according to each of Examples and Comparative Example other than Example 1 was determined as the relative light emission intensity (%). The results are shown in Table 1. FIGS. 4 to 7 show the light emission spectra of the oxide fluorescent materials according to Examples 1 to 18 and Comparative Example 1.

TABLE 1

| | | Light | Full | Relative | Light emission |
|---|---|---|---|---|---|
| | | emission | width | light | intensity at 1,000 nm |
| | | peak | at half | emission | relative to light |
| | | wavelength | maximum | intensity | emission peak wavelength |
| | Supplied composition | (nm) | (nm) | (%) | (%) |
| Example 1 | Ga₂Ge₂O₇:Cr_{0.02} | 910 | 187 | 100 | 38.0 |
| Example 2 | Ga₂Ge₂O₇:Cr_{0.04} | 917 | 205 | 114 | 57.8 |
| Example 3 | Ga₂Ge₂O₇:Cr_{0.06} | 919 | 215 | 137 | 72.6 |
| Example 4 | Ga₂Ge₂O₇:Cr_{0.08} | 927 | 193 | 94 | 67.1 |
| Example 5 | Ga₂Ge_{2.5}O₈:Cr_{0.06} | 921 | 207 | 119 | 67.1 |
| Example 6 | Ga₁Al₁Ge₂O₇:Cr_{0.06} | 892 | 186 | 119 | 28.8 |
| Example 7 | Ga_{1.5}Al_{0.5}Ge₂O₇:Cr_{0.06} | 908 | 212 | 120 | 61.6 |
| Example 8 | Ga_{1.5}In_{0.5}Ge₂O₇:Cr_{0.06} | 940 | 197 | 74 | 72.9 |
| Example 9 | Ga_{1.5}Sc_{0.5}Ge₂O₇:Cr_{0.06} | 950 | 218 | 71 | 71.5 |
| Example 10 | Ga₂Ge_{1.5}Si_{0.5}O₇:Cr_{0.06} | 911 | 280 | 113 | 63.1 |
| Example 11 | Al₂Ge₂O₇:Cr_{0.02} | 769 | 152 | 182 | 1.4 |
| Example 12 | Al₂Ge₂O₇:Cr_{0.04} | 783 | 175 | 234 | 1.0 |
| Example 13 | Al₂Ge₂O₇:Cr_{0.07} | 800 | 158 | 223 | 1.4 |
| Example 14 | Al₂Ge₂O₇:Cr_{0.10} | 819 | 174 | 226 | 3.8 |
| Example 15 | Al₂Ge_{2.5}O₈:Cr_{0.04} | 789 | 166 | 265 | 2.5 |
| Example 16 | Al₂Ge₃O₉:Cr_{0.04} | 798 | 167 | 232 | 1.8 |
| Example 17 | Al_{1.5}In_{0.5}Ge₂O₇:Cr_{0.06} | 827 | 218 | 130 | 27.1 |
| Example 18 | Al_{1.5}Sc_{0.5}Ge₂O₇:Cr_{0.06} | 809 | 215 | 129 | 14.7 |
| Comparative | Ga₄Ge₁O₈:Cr_{0.04} | 753 | 167 | 205 | 2.9 |
| Example 1 | | | | | |

As shown in Table 1 and FIGS. 4 to 7, the oxide fluorescent material according to each of Examples 1 to 18 had a light emission peak wavelength in the range of 760 nm or more and 970 nm or less in the light emission spectrum. The oxide fluorescent material according to each of Examples 1 to 10 contained Ga in the composition of the oxide fluorescent material, and thus had a light emission peak wavelength in the range of 870 nm or more and 970 nm or less in the light emission spectrum. The oxide fluorescent material according to each of Examples 1 to 18 had a full width at half maximum in the range of 150 nm or more and 290 nm or less in the light emission spectrum with the light emission peak wavelength, and converted the wavelength of the excitation light emitted from the light emitting element to emit light having a light emission spectrum with a light emission peak wavelength in a desired range, with a wider full width at half maximum, and with a light emission intensity at a desired wavelength required for analysis or other purposes.

The oxide fluorescent material according to each of Examples 1 to 10 containing Ga in the composition and Example 17 emitted light having a light emission spectrum in which a light emission intensity at 1,000 nm is 25% or more relative to the light emission intensity at the light emission peak wavelength as 100% and with a light emission intensity required for analysis in the wavelength range of 900 nm or more and 1,100 nm or more.

The oxide fluorescent material according to Comparative Example 1 had a molar ratio of Ga of more than 2 in 1 mol of the composition of the oxide fluorescent material, resulting in a light emission peak wavelength of less than 760 nm.

The oxide fluorescent material according to the present disclosure can be used in light emitting devices for medical use to obtain information inside living bodies, light emitting devices to be mounted on small mobile devices such as smartphones and smartwatches to manage physical conditions, light emitting devices used in medical devices, light emitting devices for analyzers to non-destructively measure the internal information of agricultural products such as fruits, vegetables, rice, foods, and pharmaceutical products, light emitting devices for plant cultivation to affect the photoreceptors of plants, and light emitting devices for reflection spectroscopic measuring devices used for measuring film thickness, or the like.

What is claimed is:

1. An oxide fluorescent material, having a composition represented by the following formula (1):
(Ga₁₋ᵤM¹ᵤ)₂(Ge₁₋ᵥM²ᵥ)_{w}Oₓ:Cr_{y},M³_{z} (1),
wherein M¹ represents at least one element selected from the group consisting of Al, Sc, and In; M² represents at least one element selected from the group consisting of Si, Ti, Zr, Sn, and Hf, M³ represents at least one element selected from the group consisting of Ni, Eu, Fe, Mn, Nd, Tm, Ho, Er, and Yb; and u, v, w, x, y, and z satisfy 0≤u≤1.0, 0≤v≤0.5, 1.0≤w≤3.0, 5≤x≤9, 0.005≤y≤1.0, and 0≤z≤0.5, respectively.

2. The oxide fluorescent material according to claim 1, wherein y satisfies 0.02≤y<0.08 in the formula (1).

3. The oxide fluorescent material according to claim 1, wherein u satisfies 0≤u<1.0 in the formula (1).

4. The oxide fluorescent material according to claim 1, wherein w satisfies 1.5≤w≤3.0 in the formula (1).

5. The oxide fluorescent material according to claim 2, wherein in a light emission spectrum of the oxide fluorescent material, a light emission intensity at 1,000 nm is 25% or more relative to a light emission intensity at the light emission peak wavelength.

6. The oxide fluorescent material according to claim 1, wherein the oxide fluorescent material has a full width at half maximum in a range of 150 nm or more and 290 nm or less in a light emission spectrum with a light emission peak wavelength.

7. The oxide fluorescent material according to claim 3, wherein the oxide fluorescent material has a full width at half maximum in a range of 180 nm or more and 220 nm or less in a light emission spectrum with a light emission peak wavelength.

8. The oxide fluorescent material according to claim 1, wherein the oxide fluorescent material has a light emission peak wavelength in a range of 760 nm or more and 970 nm or less.

9. The oxide fluorescent material according to claim 3, wherein the oxide fluorescent material has a light emission peak wavelength in a range of 870 nm or more and 970 nm or less.

10. A light emitting device, comprising
the oxide fluorescent material according to claim 1; and
a light emitting element having a light emission peak wavelength in a range of 365 nm or more and 650 nm or less.

11. A method for producing an oxide fluorescent material, comprising:
adjusting and mixing a first compound containing Ga and/or a second compound containing at least one first element M¹ selected from the group consisting of Al, Sc, and In, a third compound containing Ge, a fourth compound containing Cr, optionally a fifth compound containing at least one second element M² selected from the group consisting of Si, Ti, Zr, Sn, and Hf, and optionally a sixth compound containing at least one third element M³ selected from the group consisting of Ni, Eu, Fe, Mn, Nd, Tm, Ho, Er, and Yb to provide a raw material mixture such that:
when a total molar ratio of Ga and/or the at least one first element M¹ in the composition of the oxide fluorescent material is 2, a molar ratio of the at least one first element M¹ is a product of a parameter u and 2, wherein the parameter u is a numerical value of 0 or more and 1.0 or less, a molar ratio of Ga is a product of 2 and a value of 1 minus the parameter u, a molar ratio of the at least one second element M² is a product of a parameter v and a parameter w, wherein the parameter v is a numerical value of 0 or more and 0.5 or less, wherein the parameter w is a numerical value of 1.0 or more and 3.0 or less, a molar ratio of Ge is a product of the parameter w and a value of 1 minus the parameter v, a molar ratio of Cr is the parameter y, wherein the parameter y is a numerical value of 0.005 or more and 1.0 or less, a molar ratio of the at least one third element M³ is a parameter z, wherein the parameter z is a numerical value of 0 or more and 0.5 or less; and
heat-treating the raw material mixture at a temperature in a range of 800° C. or higher and 1,400° C. or lower in an atmosphere containing oxygen to obtain an oxide fluorescent material,
wherein at least one selected from the group consisting of the first compound, the second compound, the third compound, and the fourth compound comprises an oxide.

12. The method for producing an oxide fluorescent material according to claim 11, wherein the raw material mixture has a composition represented by the following formula (1):
(Ga₁₋ᵤM¹_{w})₂(Ge₁₋ᵥM²ᵥ)_{w}Oₓ:Cr_{y},M³_{z} (1),
wherein u, v, w, x, y, and z satisfy 0≤u≤1.0, 0≤v≤0.5, 1.0≤w≤3.0, 5≤x≤9, 0.005≤y≤1.0, and 0≤z≤0.5, respectively.
